(19) United States
(12) Patent Application Publication
(10) Pub. No.: US 2008/0084342 A1
(43) Pub. Date: Apr. 10, 2008

(54) Method for enhancing the driving capability of a digital to analog converter

(75) Inventors: Jun-Jie Hong, Changhua City (TW); Ming-Hwa Sheu, Yunlin County (TW); Yin-Tsung Hwang, Yunlin County (TW); Zhi-Jie Lin, Taichung County (TW)

Correspondence Address: BIRCH STEWART KOLASCH & BIRCH, PO BOX 747, FALLS CHURCH, VA, 22040-0747, US

(73) Assignee: National Yunlin University of Science and Technology

(21) Appl. No.: 11/543,907

(22) Filed: Oct. 6, 2006

(51) Int. Cl. H03M 1/66

(52) U.S. Cl. 341/144

(57) ABSTRACT

The present invention discloses a method for enhancing the driving capability of a digital to analog converter, wherein a voltage higher/lower than the intended output voltage is used to pre-charge/pre-discharge the capacitor of the output load; when the capacitor is charged/discharged to near the intended output voltage, the operation is switched back to the normal mode; and the pre-charge operation may adopt the fixed charge voltage-varying charge time mode or the fixed charge time-varying charge voltage mode.

### FIELD OF THE INVENTION

The present invention relates to a technology of a digital to analog converter, particularly to a method for enhancing the driving capability of a digital to analog converter.

### BACKGROUND OF THE INVENTION

The signals that the nature generates and human beings perceive are all continuous-time analog signals. However, the signals processed by a digital circuit are discrete-time digital signals. Therefore, a DAC (Digital to Analog Converter) is needed to transform digital signals into analog signals. DAC is widely used in electronic products, such as HDTV (High Definition TeleVision), computer systems, and audio systems. All those systems need high-speed, high-definition, and low-power consumption signal converters. DAC can be realized by many means, including by active elements or by passive elements, such as resistor type DAC, capacitor switching type DAC and current source type DAC.

Refer to FIG. 1 a block diagram schematically showing a digital to analog converter. The DAC 1 transforms input digital data into analog voltage and then outputs the analog voltage. The input signals are usually reference voltage V_{ref} or current and N-bit digital data. The relationship between the output analog voltage and the input signals can be expressed by the following equation:

Vₒᵤₜ=(b₁2⁻¹+b₂⁻²+LL+b_{N}2^{-N})V_{ref}

wherein N denotes the number of the bits of the input digital data. The resolution of an N-bit DAC can divide 2^{N} sections, and the minimum output voltage level is called LSB (Least Significant Bit).

Refer to FIG. 2 a diagram schematically showing that a buffer is externally added to a DAC. When the output load 3 of the DAC 1 is very great (such as the load resistance R_{L} and the load capacitor CL of an LCD panel), a buffer 2 is added to between the DAC 1 and the load 3 to solve the problem of insufficient driving impulses. The DAC 1 transforms input digital signals into analog signals and outputs the analog signals to a load. When the load is heavy, a buffer is used to increase the driving capability, and the output capability of the buffer must grow with the output load. However, a greater-output buffer consumes more power and occupies more chip area.

### SUMMARY OF THE INVENTION

The primary objective of the present invention is to provide a method for enhancing the driving capability of a digital to analog converter, which can reduce power consumption, and chip area, wherein the DAC needn't adopt a greater-output buffer for a heavier load and can fast charge and discharge without consuming extra power or occupying extra chip area.

The present invention utilizes an over-driving means to enhance DAC driving capability. Just like the literal meaning of the term, the over-driving means is to utilize a greater voltage (or a greater current) to pre-charge the output load capacitor; when the output capacitor is charged to near the intended output voltage, the operation is switched back to the normal mode; and the objective of fast charge/discharge is thus achieved.

When the over-driving voltage is toward the positive source voltage, a voltage greater than the originally intended output voltage is used to pre-charge the load capacitor; when the load capacitor is charged to near the originally intended output voltage, the operation is switched back to the normal charge mode. The pre-charge operation has two modes: the fixed charge voltage-varying charge time mode and the fixed charge time-varying charge voltage mode. In the fixed charge voltage mode, the pre-charge voltage is the source voltage of the analog circuit, and the pre-charge time is calculated according to capacitance of the load capacitor. In the fixed charge time mode, the pre-charge time is fixed, and the pre-charge voltage is calculated according to the capacitance of the load capacitor.

When the over-driving voltage is toward the negative source voltage, a voltage lower than the originally intended output voltage is used to pre-discharge the load capacitor; when the load capacitor is discharged to near the originally intended output voltage, the operation is switched back to the normal discharge mode. The pre-discharge operation has two modes: the fixed discharge voltage-varying discharge time mode and the fixed discharge time-varying discharge voltage mode. In the fixed discharge voltage mode, the pre-discharge voltage is the lowest voltage of the power source of the analog circuit, and the pre-discharge time is calculated according to capacitance of the load capacitor. In the fixed discharge time mode, the pre-discharge time is fixed, and the pre-discharge voltage is calculated according to the capacitance of the load capacitor.

### BRIEF DESCRIPTION OF THE DRAWINGS

FIG. 1 is a block diagram schematically showing a digital to analog converter.

FIG. 2 is a diagram schematically that a buffer is externally added to a DAC.

FIG. 3 is a diagram schematically showing the input signal and the output signal of a conventional DAC.

FIG. 4 is a diagram schematically showing the input signal and the output signal of a DAC according to the method of the present invention.

FIG. 5 is a diagram schematically showing the basic model of a buffer and the input signal and the output signal of the fixed charge voltage-varying charge time mode according to the method of the present invention.

FIG. 6 is a diagram schematically showing the basic model of a buffer and the input signal and the output signal of the fixed discharge voltage-varying discharge time mode according to the method of the present invention.

FIG. 7 is a diagram schematically showing the basic model of a buffer and the input signal and the output signal of the fixed charge time-varying charge voltage mode according to the method of the present invention.

FIG. 8 is a diagram schematically showing the basic model of a buffer and the input signal and the output signal of the fixed discharge time-varying discharge voltage mode according to the method of the present invention.

FIG. 9 is a diagram schematically showing a circuit architecture adopting the fixed charge/discharge voltage-varying charge/discharge time mode according to the method of the present invention.

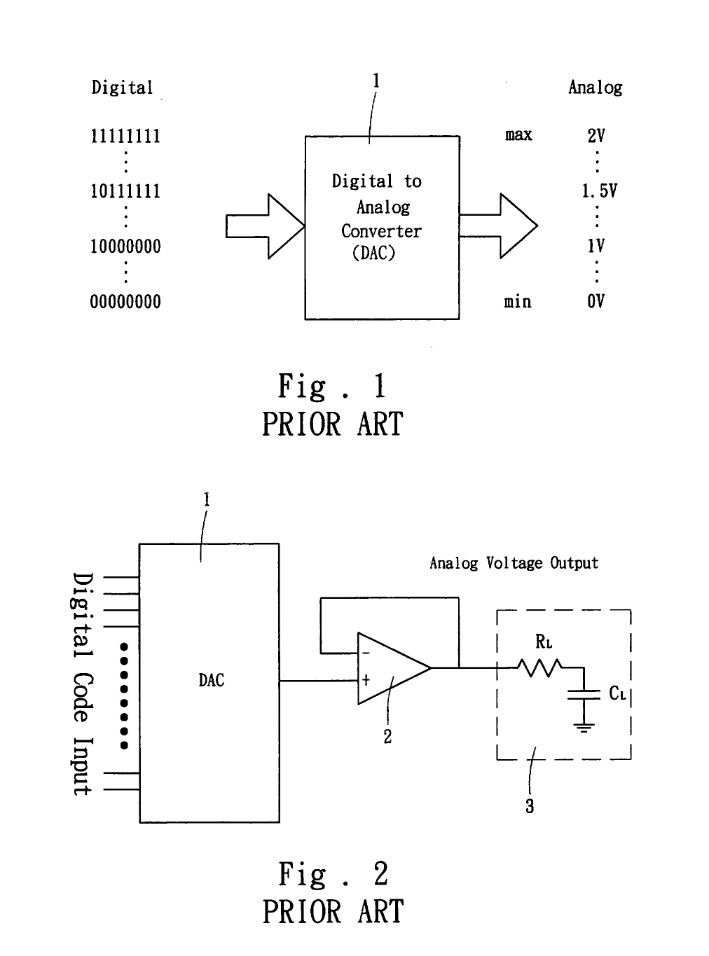

### DETAILED DESCRIPTION OF THE PREFERRED EMBODIMENTS

The technical contents of the present invention are to be described in cooperation with the drawings below.

The present invention utilizes an over-driving means to enhance DAC driving capability. Just like the literal meaning of the term, the over-driving means is to utilize a greater voltage (or a greater current) to pre-charge the output load capacitor; when the output capacitor is charged to near the intended output voltage, the operation is switched back to the normal mode; and the objective of fast charge/discharge is thus achieved.

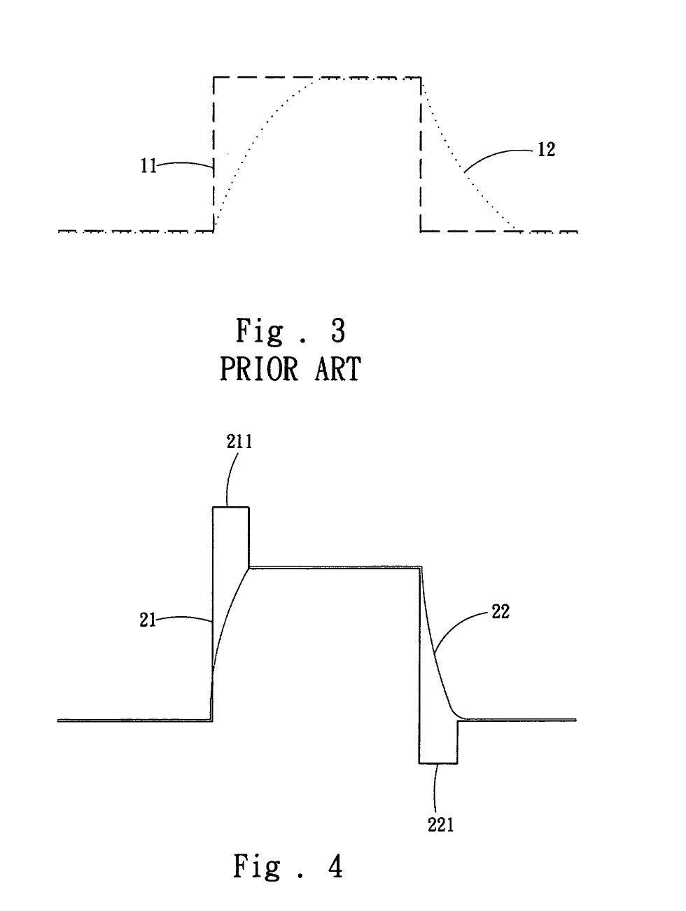

Refer to FIG. 3 a diagram schematically showing the input signal 11 and the output signal 12 of a conventional DAC. When the DAC is used to drive a heavy load, the rising edge time and the falling edge time of the output signal 12 will be too long to coincide with the input signal 11. Thus, an obvious response delay occurs in the conventional technology. The present invention proposes an over-driving means to overcome the problem caused by too long a rising edge time and too long a falling edge time. Refer to FIG. 4 a diagram schematically showing the input signal 21 and the output signal 22 of a DAC according to the method of the present invention. When a heavy output load is to be charged, a raised voltage 211 higher than the intended output voltage (a greater digital code) is used to charge the output load, and the voltage of the output load thus rises faster; thereby, the objective of fast driving is achieved. Similarly, when an output load is to be discharged, a lowered voltage 221 lower than the target voltage (a smaller digital code) is used in the discharge, and the discharge time is thus shortened.

In realizing the over-driving means of the present invention, two problems will be encountered: the first problem is how high pre-charge voltage should be, and the second problem is how long the pre-charge time should be.

In principle, the present invention fixes the value of one variable and allows the other variable to vary, i.e. the over-driving means may be roughly divided into the fixed voltage modes and the fixed time modes.

### 1. Fixed Charge Voltage-Varying Charge Time Mode:

In such a mode, the over-driving charge voltage (the digital code of the over-driving voltage) is fixed, and the over-driving charge time is variable. Under the condition that the pre-charge voltage is the source voltage Vdd of the analog circuit, the optimal pre-charge time is calculated according to the following assumption.

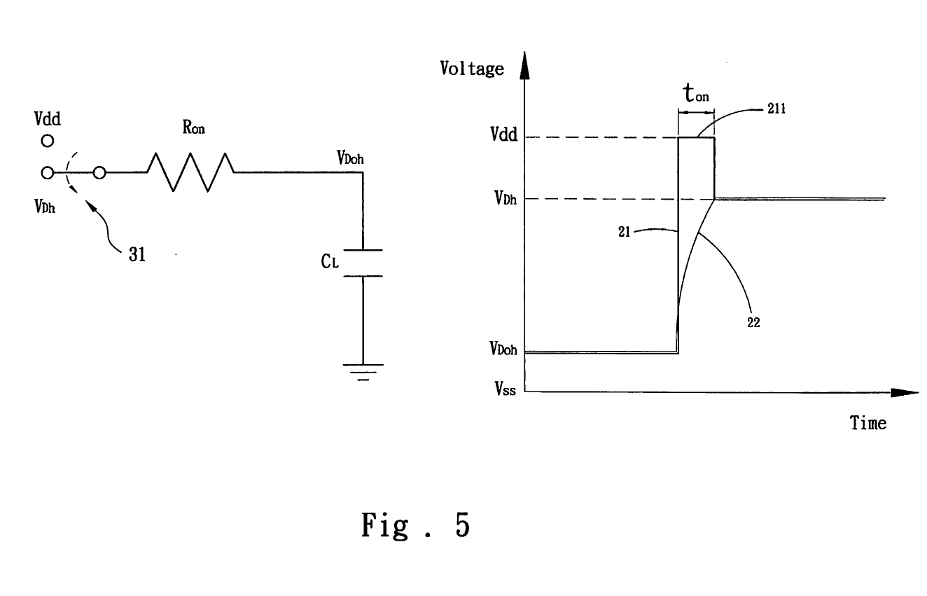

Refer to FIG. 5 a diagram schematically showing the basic model of a buffer and the input signal and the output signal of the fixed charge voltage-varying charge time mode according to the method of the present invention, wherein Rₒₙ is the charge resistor, which is the equivalent impedance of the output-stage PMOS transistor of the buffer; C_{L} is the output load; V_{Dh} is the originally intended output voltage; V_{Doh} is the last output voltage of the buffer. The output load C_{L} is intended to be charged to the voltage V_{Dh}. Suppose that V_{Dh} is greater than V_{Doh}. When the charge begins, a switch 31 is opened to enable the source voltage Vdd to perform an over-driving pre-charge on the output load C_{L}. Once the output load C_{L} is charged to near the voltage V_{Dh}, the switch 31 is shifted to the output voltage V_{Dh} of the normal mode, and then, the output voltage V_{Dh} continues to charge the output load C_{L}; thereby, the objective of fast charge is achieved.

The equation for capacitor charge can be expressed by

$${V}_{Dh} = ( Vdd - {V}_{Doh} ) \times ( 1 - {e}^{- \frac{{t}_{on}}{{R}_{on} \times {C}_{L}}} ) + {V}_{Doh} \qquad ( 1 )$$

### The opening time tₒₙ of the switch 31, i.e. the pre-charge time of the source voltage Vdd, can be calculated from Equation (1) and expressed by

$${t}_{on} ln ( \frac{Vdd - {V}_{Doh}}{Vdd - {V}_{Dh}} ) \times {R}_{on} \times {C}_{L} \qquad ( 2 )$$

In the DAC, V_{Doh} denotes the last output voltage of the DAC, and V_{Dh} denotes the voltage that the DAC currently intends to output. Therefore, the time for different V_{Doh}□V_{Dh} can be calculated from Equation (2). The optimal pre-charge time can be obtained via merely controlling the time tₒₙ of the over-driving voltage.

### 2. Fixed Discharge Voltage-Varying Discharge Time Mode:

In such a mode, the over-driving discharge voltage (the digital code of the over-driving voltage) is fixed, and the over-driving discharge time is variable. Under the condition that the pre-discharge voltage is the lowest voltage Vss of the power source of the analog circuit, the optimal pre-discharge time is calculated according to the following assumption.

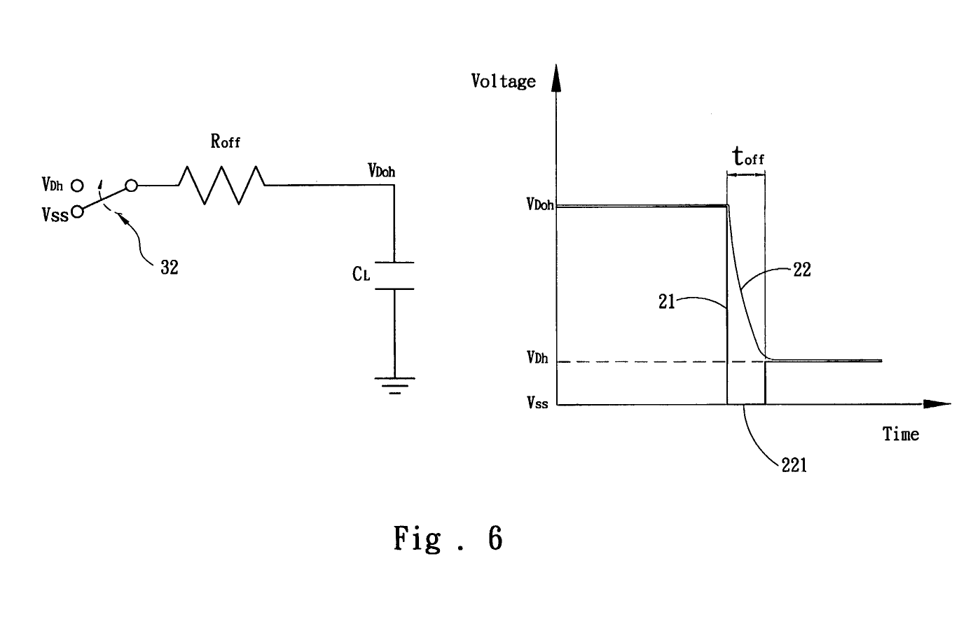

Refer to FIG. 6 a diagram schematically showing the basic model of a buffer and the input signal and the output signal of the fixed discharge voltage-varying discharge time mode according to the method of the present invention, wherein R_{off} is the discharge resistor, which is the equivalent impedance of the output-stage NMOS transistor of the buffer; C_{L} is the output load; V_{Dh} is the originally intended output voltage; V_{Doh} is the last output voltage of the buffer. The output load C_{L} is intended to be discharged to the voltage V_{Dh}. Suppose that V_{Dh} is smaller than V_{Doh}. When the discharge begins, a switch 32 is opened to enable the lowest voltage Vss of the power source to pre-discharge the output load C_{L}. Once the output load C_{L} is discharged to near the voltage V_{Dh}, the switch 32 is shifted to the output voltage V_{Dh} of the normal mode, and then, the output voltage V_{Dh} continues to discharge the output load C_{L}; thereby, the objective of fast discharge is achieved.

The equation for capacitor discharge can be expressed by

$${V}_{Dh} = {V}_{Doh} - ( {V}_{Doh} - {V}_{SS} ) \times e - \frac{{t}_{off}}{{R}_{off} \times {C}_{L}} \qquad ( 3 )$$

### The opening time t_{off} of the switch 32, i.e. the pre-discharge time of the lowest voltage Vss, can be calculated from Equation (3) and expressed by

$${t}_{off} = ln ( \frac{Vss - {V}_{Doh}}{{V}_{Dh} - {V}_{Doh}} ) \times {R}_{off} \times {C}_{L} \qquad ( 4 )$$

In the DAC, V_{Doh} denotes the last output voltage of the DAC, and V_{Dh} denotes the voltage that the DAC currently intends to output. Therefore, the time for different V_{Dh}□V_{Doh} can be calculated from Equation (4). The optimal pre-discharge time can be obtained via merely controlling the time t_{off} of the over-driving voltage.

### 3. Fixed Charge Time-Varying Charge Voltage Mode:

In such a mode, the over-driving charge time is fixed, and the over-driving charge voltage (the digital code of the over-driving voltage) is variable. Under the condition that the pre-charge time is fixed, the optimal pre-charge voltage is calculated according to the following assumption.

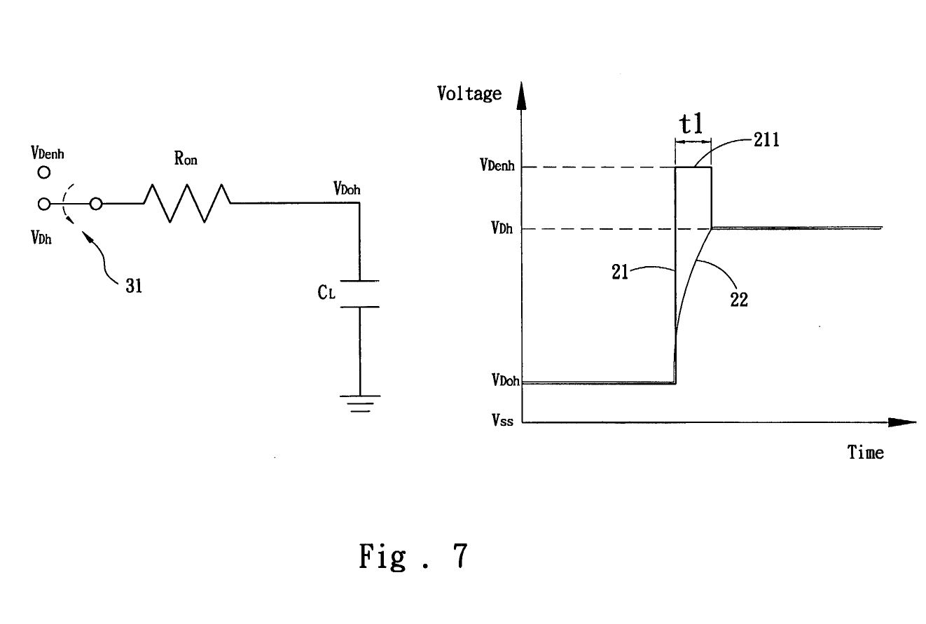

Refer to FIG. 7 a diagram schematically showing the basic model of a buffer and the input signal and the output signal of the fixed charge time-varying charge voltage mode according to the method of the present invention, wherein Rₒₙ is the charge resistor, which is the equivalent impedance of the output-stage PMOS transistor of the buffer; C_{L} is the output load; V_{Dh} is the originally intended output voltage; V_{Doh} is the last output voltage of the buffer. The output load C_{L} is intended to be charged to the voltage V_{Dh}. Suppose that V_{Dh} is greater than V_{Doh} and that the over-driving time t1 is a fixed value. When the charge begins, a switch 31 is opened to enable the over-driving voltage V_{Denh} to pre-charge the output load C_{L}. Once the output load C_{L} is charged to near the voltage V_{Dh}, the switch 31 is shifted to the output voltage V_{Dh} of the normal mode, and then, the output voltage V_{Dh} continues to charge the output load C_{L}; thereby, the objective of fast charge is achieved.

The equation for capacitor charge can be expressed by

$${V}_{Dh} = ( {V}_{Denh} - {V}_{Doh} ) \times ( 1 - {e}^{- \frac{t 1}{{R}_{on \times {C}_{L}}}} ) + {V}_{Doh} \qquad ( 5 )$$

### The required over-driving voltage V_{Denh} can be calculated from Equation (5) and expressed by

$${V}_{Denh} = \frac{{V}_{Dh} - {V}_{Doh} \times {e}^{\frac{- t 1}{{R}_{on} \times {C}_{L}}}}{1 - {e}^{\frac{- t 1}{{R}_{on} \times {C}_{L}}}} \qquad ( 6 )$$

In the DAC, V_{Doh} denotes the last output voltage of the DAC, and V_{Dh} denotes the voltage that the DAC currently intends to output. Therefore, the required over-driving voltage V_{Denh} for different V_{Doh}□V_{Dh} can be calculated from Equation (6). Once the over-driving voltage is controlled to be V_{Denh}, the over-driving time t1 will be the optimal pre-charge time.

### 4. Fixed Discharge Time-Varying Discharge Voltage Mode:

In such a mode, the over-driving discharge time is fixed, and the over-driving discharge voltage (the digital code of the over-driving voltage) is variable. Under the condition that the pre-discharge time is fixed, the optimal pre-discharge voltage is calculated according to the following assumption.

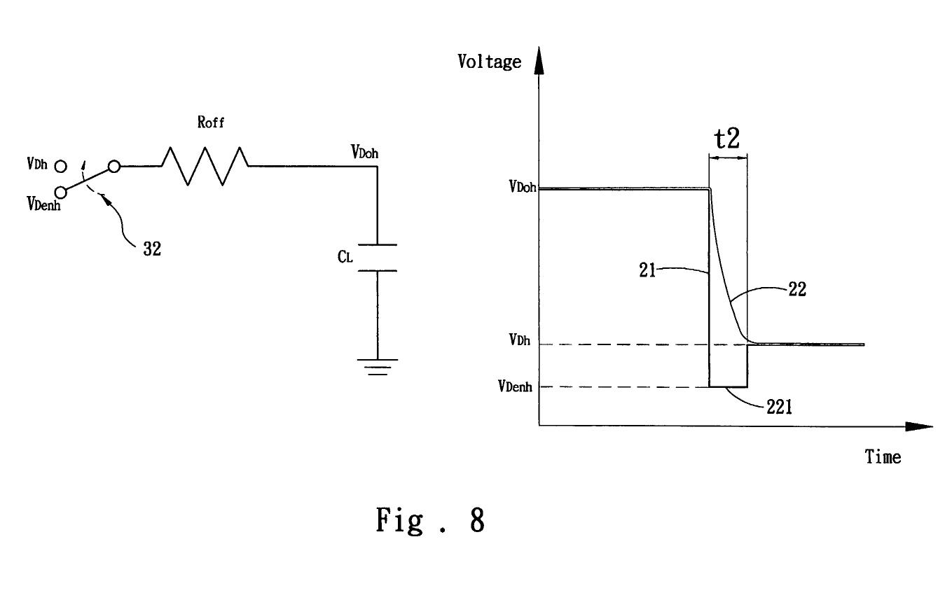

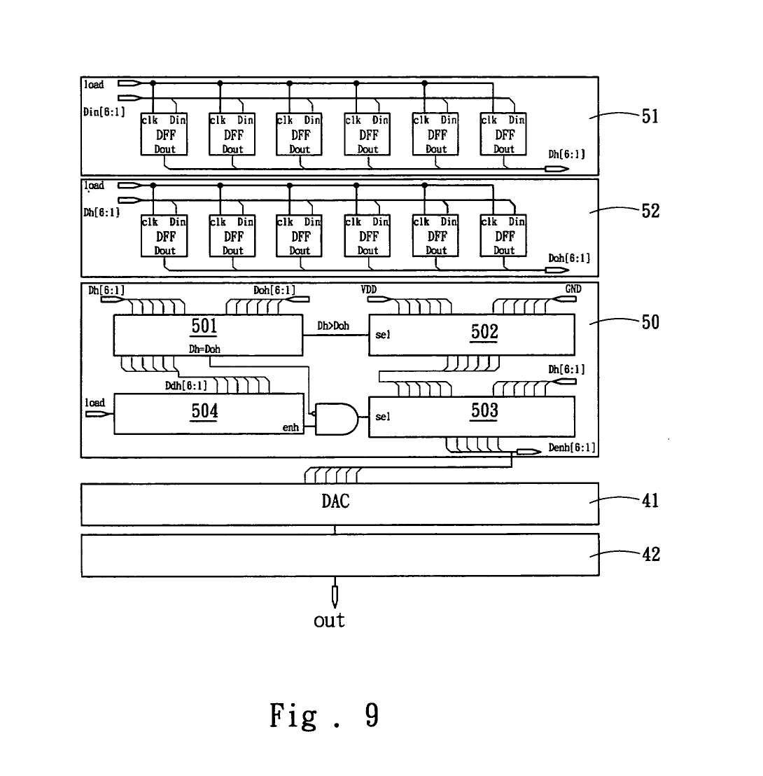

Refer to FIG. 8 a diagram schematically showing the basic model of a buffer and the input signal and the output signal of the fixed discharge time-varying discharge voltage mode according to the method of the present invention, wherein R_{off} is the discharge resistor, which is the equivalent impedance of the output-stage NMOS transistor of the buffer; C_{L} is the output load; V_{Dh} is the originally intended output voltage; V_{Doh} is the last output voltage of the buffer. The output load C_{L} is intended to be discharged to the voltage V_{Dh}. Suppose that V_{Dh} is smaller than V_{Doh} and that the over-driving time t2 is a fixed value. When the discharge begins, a switch 32 is opened to enable the over-driving voltage V_{Denh} to pre-discharge the output load C_{L}. Once the output load C_{L} is discharged to near the voltage V_{Dh}, the switch 32 is shifted to the output voltage V_{Dh} of the normal mode, and then, the output voltage V_{Dh} continues to discharge the output load C_{L}; thereby, the objective of fast discharge is achieved.

The equation for capacitor discharge can be expressed by

$${V}_{Dh} = {V}_{Doh} - ( {V}_{Doh} - {V}_{Denh} ) \times {e}^{- \frac{t 2}{{R}_{off \times {C}_{L}}}} \qquad ( 7 )$$

### The required over-driving voltage V_{Denh} can be calculated from Equation (7) and expressed by

$${V}_{Denh} = \frac{{V}_{Dh} - {V}_{Doh} \times ( 1 - {e}^{\frac{- t 2}{{R}_{off} \times {C}_{L}}} )}{{e}^{\frac{- t 2}{{R}_{off} \times {C}_{L}}}} \qquad ( 8 )$$

In the DAC, V_{Doh} denotes the last output voltage of the DAC, and V_{Dh} denotes the voltage that the DAC currently intends to output. Therefore, the required over-driving voltage V_{Denh} for different V_{Doh}□V_{Dh} can be calculated from Equation (8). Once the over-driving voltage is controlled to be V_{Denh}, the over-driving time t2 will be the optimal pre-discharge time.

Refer to FIG. 9 a diagram schematically showing a circuit architecture adopting the fixed charge/discharge voltage-varying charge/discharge time mode according to the method of the present invention. In the practical application, besides a DAC 41 and a buffer 42 receiving the output of the DAC 41, the circuit also has a first register 51, a second register 52 and an over-driving code conversion circuit 50. The over-driving code conversion circuit 50 further comprises: a difference generator/comparator 501, a first data selector 502, a second data selector 503 and a digital to time converter 504. The currently to-be-processed digital data Din is input to the first register 51, and then, the first register 51 outputs the digital data Dh, which is to be input to the DAC 41 currently, to the difference generator/comparator 501 and the second data selector 503 of the over-driving code conversion circuit 50 and to the second register 52. At this time, the second register 52 outputs the last piece of digital data Doh, which is input to the DAC 41, to the difference generator/comparator 501. The difference generator/comparator 501 creates the difference Ddh (|Dh−Doh|) between the currently input digital data Dh and the last input digital data Doh and compares the currently input digital data Dh and the last input digital data Doh. The digital to time converter 504 transforms the difference Ddh between the currently input digital data Dh and the last input digital data Doh into the variation of the corresponding over-driving time. When the currently input digital data Dh is greater than the last input digital data Doh (Dh□Doh), the first data selector 502 determines whether the over-driving is toward the positive source voltage or toward the negative source voltage, and the second data selector 503 determines whether the output to the DAC 41 is a normal output or an over-driving output. The over-driving voltage Denh varies with the difference (|Dh−Doh|). The digital to time converter 504 transforms the difference Ddh (|Dh−Doh|) output by the difference generator/comparator 501 of the over-driving code conversion circuit 50 into the time required by the over-driving operation, and then, the digital to time converter 504 counts top-down. When the digital to time converter 504 counts top-down to “0”, the logic level of the impulse enh output by the digital to time converter 504 is 0 (enh=0). For example, when Dh□Doh, and when the logic level of the impulse enh output by the digital to time converter 504 is 1, the over-driving code output by the second data selector 503 is “111111”; when Dh=Doh, and when the logic level of the impulse enh output by the digital to time converter 504 is 0, the second data selector 503 outputs the currently input digital data Dh. Further, when Dh<Doh, and when the logic level of the impulse enh output by the digital to time converter 504 is 1, the second data selector 503 outputs the over-driving code “000000”; when Dh=Doh, and when the logic level of the impulse enh output by the digital to time converter 504 is 0, the second data selector 503 outputs the currently input digital data Dh.

For example, if the currently input digital data Dh is “010111”, and if the last input digital data Doh is “000011”, the subtractor of the difference generator/comparator 501 will obtain that the difference Ddh is “010100”, and next, the difference generator/comparator 501 will determine that Dh□Doh. Then, the difference generator/comparator 501 transmits the difference Ddh to the digital to time converter 504, and the digital to time converter 504 transforms the difference Ddh into the pulse width of the corresponding over-driving time. The first data selector 502 will output “111111”. When Dh≠Doh, and when the logic level of the impulse enh output by the digital to time converter 504 is 1, the second data selector 503 outputs the over-driving code “111111”; when Dh=Doh, and when the logic level of the impulse enh output by the digital to time converter 504 is 0, the second data selector 503 outputs the currently input digital data Dh “010111”. Therefore, the digital code input to the DAC 41 will be “1111111” firstly; once the over-driving time is over, the digital code is resumed to be the original “010111”.

The spirit of the present invention is summarized as follows: The present invention utilizes an over-driving mans to enhance DAC driving capability, wherein a higher/lower voltage is used to pre-charge/pre-discharge the capacitor of the output load; when the capacitor is charged/discharged to near the originally intended output voltage, the operation is switched back to the normal mode; thereby, a heavy output load can be fast charged/discharged without using a greater-output buffer, which consumes extra power and occupies extra chip area.

Those described above are the embodiments to exemplify the present invention. However, it is not intended to limit the scope of the present invention. Any equivalent modification and variation according to the spirit of the present invention is to be also included within the scope of the present invention.

1. A method for enhancing the driving capability of a digital to analog converter, comprising:
utilizing an over-driving voltage to pre-charge and pre-discharge a capacitor of an output load; and when said output capacitor is charged/discharged to near an originally intended output voltage, switching an output back to a normal mode.

2. The method according to claim 1, wherein when said over-driving voltage is toward the positive source voltage, a voltage higher than said originally intended output voltage is used to pre-charge said capacitor of said output load; and when said output capacitor is charged to near said originally intended output voltage, the operation is switched back to the normal charge mode.

3. The method according to claim 2, wherein said pre-charge adopts a fixed pre-charge voltage-varying pre-charge time mode.

4. The method according to claim 3, wherein said fixed pre-charge voltage is the source voltage of an analog circuit; and said pre-charge time is calculated according to the capacitance of said capacitor of said output load.

5. The method according to claim 2, wherein said pre-charge adopts a fixed pre-charge time-varying pre-charge voltage mode.

6. The method according to claim 5, wherein said pre-charge time is fixed, and said pre-charge voltage is calculated according to the capacitance of said capacitor of said output load.

7. The method according to claim 1, wherein when said over-driving voltage is toward the negative source voltage, a voltage lower than said originally intended output voltage is used to pre-discharge said capacitor of said output load; and when said output capacitor is discharged to near said originally intended output voltage, the operation is switched back to the normal discharge mode.

8. The method according to claim 7, wherein said pre-discharge adopts a fixed pre-discharge voltage-varying pre-discharge time mode.

9. The method according to claim 8, wherein said fixed pre-discharge voltage is the lowest source voltage of an analog circuit; and said pre-discharge time is calculated according to the capacitance of said capacitor of said output load.

10. The method according to claim 7, wherein said pre-discharge adopts a fixed pre-discharge time-varying pre-discharge voltage mode.

11. The method according to claim 10, wherein said pre-discharge time is fixed, and said pre-discharge voltage is calculated according to the capacitance of said capacitor of said output load.
